(19) United States
(12) Patent Application Publication
(10) Pub. No.: US 2024/0381542 A1
(43) Pub. Date: Nov. 14, 2024

(54) METHOD FOR ALIGNING CONTACT SURFACES OF AN ELECTRICAL AND/OR ELECTRONIC COMPONENT, IN PARTICULAR OF A MAGNETIC COMPONENT

(71) Applicant: Robert Bosch GmbH, Stuttgart (DE)

(72) Inventor: Jivan Kapoor, Stuttgart (DE)

(21) Appl. No.: 18/692,932

(22) PCT Filed: Aug. 25, 2022
(86) PCT No.: PCT/EP2022/073642

§ 371 Date: Mar. 18, 2024

(30) Foreign Application Priority Data
Oct. 13, 2021 (DE) 10 2021 211 521.7

(51) Int. Cl. H05K 3/34; H05K 1/02

(52) U.S. Cl. CPC H05K 3/3426; H05K 1/0203; H05K 1/0212; H05K 3/3494; H05K 2201/09072

(57) ABSTRACT

A method for aligning contact surfaces (11, 21) of an electrical and/or electronic component (1), in particular of a magnetic component, is proposed. The method comprises a step (100) for providing the electrical and/or electronic component (1), wherein the electrical and/or electronic component (1) comprises at least one electrically conductive first contacting element (10) for electrically contacting the electrical and/or electronic component (1) with a conductor substrate,
wherein a planar first contact surface (11) is formed on the first contacting element (10), wherein a planar second contact surface (21) is furthermore formed on the electrical and/or electronic component (1), wherein the first contacting element (10) is held by a holding part (4) on the electrical and/or electronic component (1), a step (300) for aligning the contact surfaces (11, 21), wherein the electrical and/or electronic component (1) is pressed against a baseplate (50) having a first bearing surface (51) and a second bearing surface (52), wherein the first contact surface (11) is pressed against the first bearing surface (51) of the baseplate (50) and the second contact surface (21) is pressed against a second bearing surface (52) on the baseplate (50) and the first contact surface (11) and the second contact surface (12) are aligned relative to one another.

### BACKGROUND

The present invention relates to a method for aligning contact surfaces of an electrical and/or electronic component, in particular a magnetic component.

Electrical and or electronic components, for example inductive components, are often designed as SMD parts for reflow soldering processes. For this purpose, they have contacting elements, for example in the form of solder pins, on which contact surfaces are formed that are soldered to a conductor substrate. An essential prerequisite for applying the SMD parts to the conductor substrates using reflow soldering processes is suitable coplanarity between the contact surfaces of the individual contacting elements. The typical coplanarity target value for this is 100 μm for a package with multiple contact surfaces. Coplanarity is usually achieved by mechanically aligning the contact surfaces of the contacting elements with each other.

### SUMMARY

According to the invention, a method for aligning contact surfaces of an electrical and/or electronic component, in particular a magnetic component, is proposed.

The method comprises a step of providing the electrical and/or electronic component, wherein the electrical and/or electronic component comprises at least one electrically conductive first contacting element for electrically contacting the electrical and/or electronic component to a conductor substrate. A planar first contact surface is formed on the first contacting element. Furthermore, a planar second contact surface is formed on the electrical and/or electronic component, wherein the first contacting element is held by a holding part on the electrical and/or electronic component. The method further comprises a step of aligning the contact surfaces, wherein the electrical and/or electronic component is pressed against a baseplate having a first bearing surface and a second bearing surface, wherein the first contact surface is pressed against the first bearing surface of the baseplate and the second contact surface is pressed against a second bearing surface on the baseplate, and the first contact surface and the second contact surface are thus aligned relative to each other.

Compared to the prior art, the method according to the invention has the advantage that the first contact surface and the second contact surface can be aligned relative to each other, in particular coplanar to each other, with an advantageously low tolerance. The advantageously precise alignment of the contact surfaces with respect to one another can advantageously facilitate the application of the electrical and/or electronic component to the conductor substrate. The electrical and/or electronic components can be easily applied to and contacted with the conductor substrate by SMD soldering processes. The first contact area and the second contact area of the electrical and/or electronic component can advantageously be well applied to the conductor substrate by means of reflow soldering due to the low-tolerance alignment to each other.

According to an advantageous exemplary embodiment, it is provided that the first bearing surface and the second bearing surface are arranged to be coplanar to each other, so that the first contact surface and the second contact surface of the electrical and/or electronic component are aligned to be coplanar to each other during the step for aligning the contact surfaces. The contact surfaces, which are thus aligned to be coplanar to each other, can thus be attached to the conductor substrate by means of reflow soldering, for example.

According to an advantageous exemplary embodiment, it is provided that at least one recess is formed in the baseplate, wherein a region of the electrical and/or electronic component protruding beyond the first contact surface and/or beyond the second contact surface of the electrical and/or electronic component in a pressing direction dips into the recess in the baseplate without touching the baseplate. This ensures that when the electrical and/or electronic component is pressed against the baseplate, the contact surfaces come into contact with the bearing surfaces on the baseplate and can be aligned with them.

According to an advantageous exemplary embodiment, it is provided that the method further comprises a step for heating the holding part, wherein the holding part is heated so that the first contacting element with the first contact surface is movable relative to the second contact surface of the electrical and/or electronic component, wherein the holding part is formed in particular of plastic. Heating the holding part, which is made of plastic, for example, softens the holding part and the contacting element thus becomes movable. In particular, the holding part is heated only in the region in which the contacting element is held by the holding part. This is, for example, the region where the holding part is in direct contact with the contacting element. Thus, when the first contact surface is pressed onto the first bearing surface on the baseplate, the contacting element is movable in the softened holding part and the contacting element is aligned so that the first contact surface of the contacting element bears against the first bearing surface on the baseplate. Heating the holding part thus enables the necessary moderate repositioning of first contacting element by gentle application of force to the contacting element, while the entire electrical and/or electronic component is pressed against the baseplate. If the holding part is then no longer heated, the holding part solidifies again and the holding part is fixed in the desired position.

According to an advantageous exemplary embodiment, it is provided that the holding part is heated by a current flow through the first contacting element. Advantageously, the region of the holding part around the contacting element can be heated and thus softened. The contacting element can thus be aligned particularly well relative to the holding part when the first contact surface is pressed against the baseplate. Thus, the contacting element becomes movable in the holding part and at the same time the holding part remains stable as a whole.

According to an advantageous exemplary embodiment, it is provided that the holding part is heated by a laser, wherein the laser heats the holding part directly or the first contacting element held by the holding part. The laser can advantageously heat and soften only the region of the holding part around the contacting element. Thus, the contacting element becomes movable in the holding part and at the same time the holding part remains stable as a whole.

According to an advantageous exemplary embodiment, the method further comprises a step of solidifying the holding part, wherein a flow of air is directed onto the holding part to solidify the holding part. Thus, after alignment of the contacting element, the holding part can be quickly re-solidified and the contacting element can be fixed in the holding part.

According to an advantageous exemplary embodiment, the method further comprises a step of inserting a flowable and curable mass, in which the flowable and curable mass is inserted into an interspace between the holding part and the contacting element. In this process, the flowable and curable compound is cured after insertion so that the contacting element is fixed in the holding part. Due to the interspace between the holding part and the contacting element, the contacting element is easily movable relative to the holding part, so that the contacting element can be aligned during the step for aligning the contact surfaces by bringing the first contact surface into contact with the first bearing surface of the baseplate. Curing of the flowable and curable compound fixes the contacting element in the holding part so that it is no longer movable relative to the holding part.

According to an advantageous exemplary embodiment, it is provided that the first contacting element is formed as a pin having a foot for SMD soldering of the pin on a conductor substrate, wherein the first contact area is formed at the foot of the pin. The contact surfaces, which are aligned with each other, can advantageously be applied well to the conductor substrate, for example by means of reflow soldering.

According to an advantageous exemplary embodiment, it is provided that the second contact area is formed on a second contacting element of the electrical and/or electronic component, wherein a foot for SMD soldering of the second contacting element to a conductor substrate is formed on the second contacting element and the second contact area is formed on the second foot of the second contacting element. The two contacting elements are then aligned with each other in such a way that they can be advantageously and easily applied to the conductor substrate, for example by means of a reflow soldering process.

### BRIEF DESCRIPTION OF THE DRAWINGS

Exemplary embodiments of the invention are illustrated in the drawings and are explained in more detail in the following description. The figures show:

FIG. 1 a schematic representation of the method for aligning contact surfaces of an electrical and/or electronic component,

FIG. 2 an illustration of an exemplary embodiment of the holding part of an electrical and/or electronic component.

### DETAILED DESCRIPTION

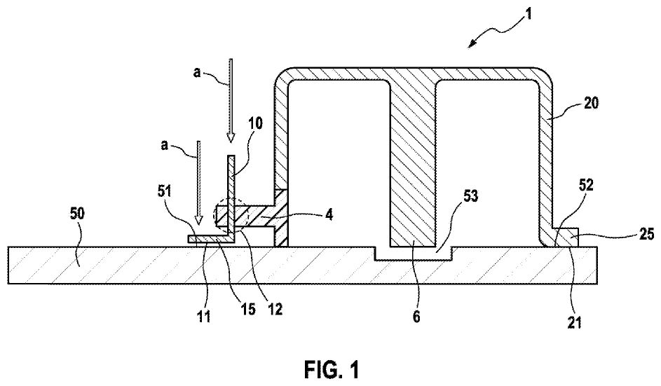

FIG. 1 shows an exemplary embodiment of an electrical and/or electronic component 1 in which the first contact surface 11 and the second contact surface 21 can be aligned relative to one another by means of the method. The electrical and/or electronic component 1 shown here is formed as a magnetic component and comprises, for example, a magnetic core, which is not shown, and an electrical conductor, which is not shown, wound around the magnetic core and may be formed, for example, as a stranded wire. The end of the conductor can be electrically conductively connected to a contacting element 10. The contacting element 10 is pin-shaped, in particular as an SMD pin. The first contacting element 10 is formed from an electrically conductive metal, for example copper or aluminum. The end of the conductor is wrapped around the contacting element 10, for example, which is formed as a pin. The contacting element 10 is provided for electrically contacting the conductor to a conductor substrate. For this purpose, the contacting element 10 can be soldered to the conductor substrate, for example, and thus an electrically conductive connection can be established between the contacting element 10 and a conductor track of the conductor substrate. The conductor substrate can, for example, be a printed circuit board or an IMS substrate. A contact surface 11 is formed on the contacting element 10 for soldering to the conductor substrate. The contact surface 11 is formed on a foot 15 of the contacting element 10. The contact surface 11 faces the conductor substrate. The contacting element 10 is, for example, in the form of a flat pin that is bent over to form the foot 15 at the end facing the conductor substrate. The electrical and/or electronic component 1 further comprises a second contact surface 21. In this exemplary embodiment, the second contact surface 21 is formed on a second contacting element 20. The second contacting element 20 is provided for electrically contacting the electrical and/or electronic component 1 with the conductor substrate. In this exemplary embodiment, the second contacting element 20 is pot-like and covers the magnetic core in the manner of a pot housing. The second contact surface 21 is formed on a second foot 25 of the second contacting element 20. The second contacting element 20 is formed of an electrically conductive metal, for example, copper or aluminum. The second foot 25 of the second contacting element 20 is provided to contact the pot housing to the conductor substrate, for example an IMS substrate, and thus to establish an electrical and thermal connection of the pot housing to the conductor substrate. However, the second contacting element 20 may also have other shapes and, for example, may also be pin-like, like the first contacting element 10. In principle, different types of electrical and/or electronic components 1 with at least one first contact surface 11 and at least one second contact surface 21 can be processed by means of the method and thus the contact surfaces 11, 21 can be aligned relative to one another. The contact surfaces 11, 21 are in particular surfaces of electrically conductive elements of the electrical and/or electronic component 1, which serve to make electrical contact with the electrical and/or electronic component 1 and/or which are formed to be applied to a conductor substrate, for example by means of SMD technology. However, the second contact surface 21 may also be, for example, a non-conductive surface, for example on a housing of the electrical and/or electronic component 1. The second contact surface 21 serves as a reference surface to which the first contact surface 11 is aligned.

FIG. 1 shows the method for aligning the first contact surface 11 relative to the second contact surface 21. The first contact surface 11 is aligned to be coplanar to the second contact surface 21. A first contact surface 11 and a second contact surface 21 are formed on the electrical and/or electronic component 1. The contact areas 11, 21 are provided for electrically contacting the electrical and/or electronic component 1 on a conductor substrate, in particular with conductor tracks of the conductor substrate. For this purpose, the contact surfaces 11, 21 are arranged essentially plane-parallel to each other. The first contact surface 11 is formed on a first foot 15 of a first contacting element 10. The second contact surface 12 formed with a second foot 15 of a second contacting element 20. The contacting elements 10, 20 can be pin-shaped, for example. The contacting elements 10, 20 are formed of an electrically conductive material, for example a metal, for example copper. Here, the first contacting element 10 is pin-shaped, with the pin being bent over at one end to form the first foot 15 of the contacting element 10. In this exemplary embodiment, the second contacting element 20 is pot-shaped. However, the second contacting element 20 can, for example, also be pin-shaped like the first contacting element 10 or have other shapes.

The first contacting element 10 is held by a holding part 4. For this purpose, a recess is provided in the holding part 4 through which the contacting element 10 is passed. A central portion of the contacting element 10 is embedded in the holding part 4. The two ends of the contacting element 10, which is substantially pin-shaped, for example, protrude from the holding part 4. The holding part 4 protrudes from the electrical and/or electronic component 1, for example. The holding part 4 surrounds the contacting element 10 and thereby holds the contacting element 10 on the electrical and/or electronic component 1. The holding part 4 is made of a plastic, for example. The holding part 4 may be softened by heat, so that the contacting element 10 becomes easily movable in the holding part 4.

As shown in FIG. 1, the method involves pressing the electrical and/or electronic component 1 against a baseplate 50 in a pressing direction a. A first bearing surface 51 is formed on the baseplate 50, against which the first contact surface 11 of the electrical and/or electronic component 1 is pressed. Furthermore, a second bearing surface 52 is formed on the baseplate 50, against which the second contact surface 21 of the electrical and/or electronic component 1 is pressed. The first bearing surface 51 and the second bearing surface 52 are flat and plane-parallel to each other. Furthermore, recesses 53 may be formed in the baseplate 50, for example, between the first bearing surface 51 of the second bearing surface 52 or at other locations on the baseplate 50. The electrical and/or electronic component 1 is pressed against the baseplate 50 in the pressing direction a, so that the first contact surface 11 bears flat against the first bearing surface 51 of the baseplate 50 and at the same time the second contact surface 12 bears flat against the second bearing surface 51 of the baseplate 50. Due to the fact that the first contacting element 10 is slightly movable in the holding part 4, the contacting element 10 is aligned in the holding part 4 in such a way that both the first contact surface 11 bears flat against the first bearing surface 51 and the second contact surface 21 bears flat against the second bearing surface 52. Due to the fact that the first bearing surface 51 and the second bearing surface 52 are arranged plane-parallel to each other, the first contact surface 11 and the second contact surface 12 of the electrical and/or electronic component 1 are also aligned plane-parallel to each other. The first bearing surface 51 and the second bearing surface 52 of the baseplate 50 thus serve as coplanar reference surfaces on which the first contact surface 11 and the second contact surface 21 are aligned to be coplanar to each other. Regions 6 of the electrical and/or electronic component 1 protruding beyond the contact surfaces 11, 21 in the pressing direction a can thereby dip into the recesses 53 in the baseplate 50 without the protruding regions 6 touching the baseplate 50. Thus, it can be ensured that the first contact surface 11 and the second contact surface 21 can be pressed against the first bearing surface 51 and the second bearing surface 52 by the method and thus be aligned to be coplanar to each other. In particular, the pressure direction a can be perpendicular to the second bearing surface 52. The forces for pressing the electrical and/or electronic component 1 can be applied by simple mechanical means and tools, such as a metal jet, which exerts a defined force on the electrical and/or electronic component 1 and in particular on the contacting element 10.

Before and/or while the electrical and/or electronic component 1 is pressed against the baseplate 50, the holding part 4 can be heated. By heating the holding part 4, the material of the holding part 4 becomes softer and the first contacting element 10, which is held by the holding part 4, can be moved in the softened holding part 4. When the electrical and/or electronic component 1 is pressed against the baseplate 50, the contacting element 10 is aligned in the heated holding part 4 in such a way that the first contact surface 11 bears flat against the first bearing surface 51 of the baseplate 50 and, at the same time, the second contact surface 21 bears flat against the second bearing surface 52 of the baseplate 50. In this case, the first contacting element 10 cannot yet initially touch the baseplate 50 and can only be pressed onto the baseplate 50 and thus aligned with it when the first contacting element 10 has become movable due to the heating of the holding part 4.

The heating of the holding part 4 takes place in particular in the region 12 in which the holding part 4 surrounds the first contacting element 10. For example, the heating can be performed by a current flow through the first contacting element 10 so that the region 12 in which the holding part 4 surrounds the first contacting element 10 is specifically heated. Furthermore, the holding part 4 can be heated by a laser, for example. In doing so, the laser can heat the holding part 4 directly or the first contacting element 10 held by the holding part 4. When the contacting element 10 is heated, the region 12 of the holding part 4 around the contacting element 10 is indirectly heated. Furthermore, the heating of the holding part 4 can also be performed, for example, by a soldering or welding process on the contacting element 10, in which the contacting element 10 is contacted in the electrical and/or electronic component 1, for example with the end 33 of the conductor 32. If, for example, the end 33 of the conductor 32, which may be in the form of a stranded wire, is welded or soldered in a forked end of the contacting element 10, the heat generated can be used to heat the holding part 4 in the region 12 around the contacting element 10 and to align the contact surfaces 11, 21 to be coplanar to one another using the method described.

When the heating of the holding part 4 is finished, the holding part 4 solidifies again and the contacting element 10 is fixed in the holding part 4. To solidify the holding part 4, an additional air flow can be used, which is directed to the previously heated region 12 of the holding part 4. After the holding part 4 has solidified again, the first contact surface 11 is also fixed relative to the second contact surface 21.

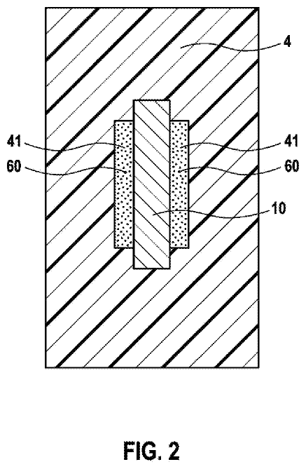

Further, the method may comprise a step of inserting a flowable and curable composition 60 into an interspace 41 between the holding part 4 and the contacting element 10. FIG. 2 shows a cross-section through an exemplary embodiment of the holding part 4 of FIG. 1 in a plane perpendicular to the pressing direction a. A recess is formed in the holding part 4 through which the contacting element 10 is passed. In this exemplary embodiment, the contacting element 10 is in direct contact with the holding part 4 on two sides. The contacting element 10 is embedded in the holding part 4 on the two sides, for example. The contacting element 10 is thereby held in the holding part 4 and thus on the electrical and/or electronic component 1. Interspaces 41 are formed between the holding part 4 and the contacting element 10 on two sides of the contacting element 10 between the contacting element 10 and the holding part 4. The holding part 4 is spaced from the contacting element 10 by the interspaces 41. Due to the interspaces 41, the contacting element 10 is slightly flexible with respect to the holding part 4 and can be moved slightly within it. Thus, with a holding part 4 formed in this way, the contacting element 10 can be moved when the electrical and/or electronic component 1 is pressed onto the baseplate 50, so that the first contact surface 11 bears flat against the first bearing surface 51 and, at the same time, the second contact surface 21 bears against the second bearing surface 52. Further, before or after the electrical and/or electronic component 1 is pressed against the baseplate 50, a flowable and curable compound 60 may be inserted into the interspaces 41 between the holding part 4 and the contacting element 10. The flowable and curable compound 60 may be in the form of an adhesive, for example. The interspaces 41 between the holding part 4 and the contacting element 10 can, for example, be formed narrowly such that the flowable and curable compound 60 is drawn into the interspaces 41 by capillary forces. After pressing the electrical and/or electronic component 1 against the baseplate 50, the flowable and curable compound 60 can be cured in the interspaces 41 between the holding part and the contacting element 10. Curing can be photoinduced, for example. The curing of the flowable and curable compound 60 fixes the contacting element 10 in the holding part 4, so that the first contact surface 11 and the second contact surface 21 of the electrical and/or electronic component 1 are also fixed relative to each other.

Of course, further exemplary embodiments and mixed forms of the illustrated exemplary embodiments are also possible.

1. A method for aligning contact surfaces (11, 21) of an electrical and/or electronic component (1), the method comprising:
providing the electrical and/or electronic component (1), wherein the electrical and/or electronic component (1) comprises at least one electrically conductive first contacting element (10) for electrically contacting the electrical and/or electronic component (1) with a conductor substrate,
wherein a planar first contact surface (11) is formed on the first contacting element (10), wherein a planar second contact surface (21) is further formed on the electrical and/or electronic component (1), wherein the first contacting element (10) is held by a holding part (4) on the electrical and/or electronic component (1),
aligning the contact surfaces (11, 21), wherein the electrical and/or electronic component (1) is pressed against a baseplate (50) having a first bearing surface (51) and a second bearing surface (52), wherein the first contact surface (11) is pressed against the first bearing surface (51) of the baseplate (50) and the second contact surface (21) is pressed against a second bearing surface (52) on the baseplate (50), and the first contact surface (11) and the second contact surface (12) are aligned relative to each other.

2. The method according to claim 1, wherein the first bearing surface (51) and the second bearing surface (52) are arranged to be coplanar to each other, so that the first contact surface (11) and the second contact surface (21) of the electrical and/or electronic component (1) are aligned to be coplanar to each other during the step of aligning the contact surfaces (11, 21).

3. The method according to claim 1, wherein at least one recess (53) is formed in the baseplate (50), wherein a region (6) of the component (1) protruding beyond the first contact surface (11) and/or beyond the second contact surface (21) of the component (1) in a pressing direction (a) dips into the recess (53) in the baseplate (50) without touching the baseplate (50).

4. The method according to claim 1, wherein the method further comprises heating the holding part (4), wherein the holding part (4) is heated so that the first contacting element (10) with the first contact surface (11) is movable relative to the second contact surface (21) of the electrical and/or electronic component (1).

5. The method according to claim 4, wherein the holding part (4) is heated by a current flow through the first contacting element (10).

6. The method according to claim 4, wherein the holding part (4) is heated by a laser, the laser heating the holding part (4) directly, or indirectly via the first contacting element (10) held by the holding part (4).

7. The method according to claim 4, wherein the method further comprises a step of solidifying the holding part (4), wherein an air flow is directed onto the holding part (4) to solidify the holding part (4).

8. The method according to claim 1, wherein the method further comprises inserting a flowable and curable mass (60), wherein the flowable and curable mass (60) is inserted into an interspace (41) between the holding part (4) and the contacting element (10), wherein the flowable and curable mass (60) is cured after the insertion, so that the contacting element (10) is fixed in the holding part (4).

9. The method according to claim 1, wherein the first contacting element (10) is formed as a pin having a first foot (15) for SMD soldering the pin to a conductor substrate, wherein the first contact area (11) is formed on the first foot (15) of the pin.

10. The method according to claim 1, wherein the second contact area (21) is formed on a second contacting element (20) of the electrical and/or electronic component (1), wherein a second foot (25) for SMD soldering of the second contacting element (20) to a conductor substrate is formed on the second contacting element (20), and the second contact area (21) is formed on the second foot (25) of the second contacting element (20).

11. The method according to claim 1, wherein the electrical and/or electronic component (1) is a magnetic component.

12. The method according to claim 4, wherein the holding part (4) is formed from plastic.

13. The method according to claim 5, wherein the method further comprises solidifying the holding part (4), wherein an air flow is directed onto the holding part (4) to solidify the holding part (4).

14. The method according to claim 6, wherein the method further comprises solidifying the holding part (4), wherein an air flow is directed onto the holding part (4) to solidify the holding part (4).
